(19) United States
(12) Patent Application Publication
(10) Pub. No.: US 2007/0045853 A1
(43) Pub. Date: Mar. 1, 2007

(54) Method for forming metal line, method for manufacturing semiconductor device using the method, and semiconductor device

(75) Inventor: Lee Chang Myung, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/512,305

(22) Filed: Aug. 30, 2006

(30) Foreign Application Priority Data
Aug. 30, 2005 (KR) 10-2005-0080125

(51) Int. Cl. H01L 21/44

(52) U.S. Cl. 257/762; 438/687

(57) ABSTRACT

Provided is a method for forming a metal line. According to the method, a silicon carbide (SiC) layer is formed on a semiconductor substrate, a silicon oxide layer is formed on the silicon carbide layer, the silicon oxide layer including an alkyl group, and a via hole and a trench are formed by removing a portion of the silicon oxide layer. Subsequently, a diffusion barrier is formed on remaining portions of the silicon oxide layer, a copper seed layer is formed on the diffusion barrier, and a copper metal layer is formed on the copper seed layer using electroplating.

### RELATED APPLICATION

This application is based upon and claims the benefit of priority to Korean Application No. 10-2005-0080125, filed on Aug. 30, 2005, the entire contents of which are incorporated herein by reference.

### BACKGROUND

1. Technical Field

The present invention relates to a method for forming a metal line, a method for forming a semiconductor device using the method for forming a metal line, and a semiconductor device produced from the aforementioned methods.

2. Description of the Related Art

In order to produce a semiconductor device capable of both high speed and high integration, it is beneficial to use processing technology which includes the use of materials including copper and low dielectrics. A semiconductor manufacturing process is divided into a front end of the line (FEOL) where transistors (TRs) are formed in a silicon substrate, and a back end of the line (BEOL) where lines are formed.

Conventional semiconductor wiring technology realizes a path for power and signal transfer that constitutes a circuit by interconnecting TRs in a semiconductor integrated circuit (IC). In a multi-layered wiring process, capacitance between densely arranged metal lines and the resistance of a fine metal line increases, a resistance-capacitance (RC) delay effect occurs, which reduces an operating speed of a device. A study for solving the RC delay using low-k insulating material and a metal material such as copper having high conductivity is in progress.

For an intermetallic dielectric (IMD) of next generation semiconductor metal lines, use of low-k material having k of 3.0 or less is under consideration. A dielectric constant k of an oxide (e.g., SiO₂) used for an IMD in a related art is in a range of 3.2-4.2, which is too high and causes a serious problem to the high integration and high speed desired in a semiconductor chip.

Particularly, when only aluminum wiring is replaced by copper, high integration and high speed of a semiconductor chip cannot be accomplished without the use of a low-k material.

The importance of a low-k material is descried below.

First, reduction of an RC signal delay given by the product of a resistance of a wiring material and a capacitance of an IMD is indispensable for obtaining a high speed of a device.

Second, when a low-k material is used, crosstalk can be prevented, so that a concentration of a circuit increases and thus high integration and miniaturization are achieved.

Third, efforts are currently being made in the development of semiconductor circuits to reduce the power consumption of a semiconductor chip so that the semiconductor chip can support the wireless or mobile Internet. In this aspect, it is indispensable to replace a related art aluminum/oxide wiring structure with a copper/low-k material. Therefore, when a copper metal line and a low-k insulating material are used, a process is simplified, manufacturing costs are reduced, and chip performance is remarkably improved.

### SUMMARY

Accordingly, embodiments consistent with the present invention are directed to a method for forming a metal line, a method for forming a semiconductor device using the method, and a semiconductor device that substantially obviate one or more problems due to limitations and disadvantages of the related art.

An embodiment consistent with the present invention provides a method for forming a copper metal line including an interlayer insulating layer having excellent thermal and mechanical characteristics using a black diamond layer, which is a low-k material.

Another embodiment consistent with the present invention provides a method for forming a copper metal line having an optimized etch profile by etching a via hole and a trench through an etching process using a reactive ion etching (RIE) method that utilizes a dual frequency.

A further embodiment consistent with the present invention provides a method for forming a copper metal line having a low dielectric constant by restoring carbon concentration of a copper metal line that uses a black diamond layer, which is a low-k material, to a normal concentration using a solution NE14.

Additional advantages and features of the invention will be set forth in part in the description which follows and in part will become apparent to those having ordinary skill in the art upon examination of the following or may be learned from practice of the invention. The features and other advantages of the invention may be realized and attained by the structure particularly pointed out in the written description and claims hereof as well as the appended drawings.

Consistent with the present invention, as embodied and broadly described herein, there is provided a method for forming a metal line in a semiconductor device, the method including: forming a silicon carbide (SiC) layer on a semiconductor substrate; forming a silicon oxide layer on the silicon carbide layer, the silicon oxide layer including an alkyl group; forming a via hole and a trench by removing a portion of the silicon oxide layer; forming a diffusion barrier on remaining portions of the silicon oxide layer; forming a copper seed layer on the diffusion barrier; and forming a copper metal layer on the copper seed layer using electroplating.

In another embodiment consistent with the present invention, there is provided a method for manufacturing a semiconductor device, the method including: forming a first oxide layer on a semiconductor substrate; forming a silicon carbide layer on the first oxide layer; forming a silicon oxide layer on the silicon carbide layer, the silicon oxide layer including an alkyl group; forming a second oxide layer on the silicon oxide layer; forming a via hole and a trench by removing a portion of the silicon oxide layer and the second oxide layer; forming a diffusion barrier on remaining portions of the silicon oxide layer and the second oxide layer; forming a copper seed layer on the diffusion barrier; and forming a copper metal layer on the copper seed layer using electroplating.

In a further embodiment consistent with the present invention, there is provided a semiconductor device including: a silicon carbide layer formed on a semiconductor substrate; a silicon oxide layer formed on the silicon carbide layer, the silicon oxide layer including an alkyl group; a via hole and a trench formed in the silicon oxide layer; a copper diffusion barrier formed on inner sidewalls of the via hole and the trench ; and a copper metal layer formed on the copper diffusion barrier and filling the via hole and the trench.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) consistent with the invention and together with the description serve to explain the principle of the invention. In the drawings:

FIGS. 1 to 5 are cross-sectional views sequentially explaining a process for forming a metal line consistent with an embodiment of the present invention;

FIG. 6A shows a Scanning Electron Microscope (SEM) image of a via hole;

FIG. 6B shows an SEM image of a trench etched in a stacked structure including a black diamond layer, which is a low-k material;

FIGS. 7A and 7B are SEM images after only an ashing process is performed and after an ashing process and an NE14 treatment are performed, respectively;

FIG. 8 is a graph illustrating contact resistance with respect to a via hole after an NE14 treatment;

FIG. 9A is an SIMS graph illustrating carbon concentration after only an ashing process is performed;

FIG. 9B is an SIMS graph illustrating carbon concentration after an ashing process and an NE14 treatment are performed in a copper line that uses a black diamond layer, which is a low-k material;

FIG. 10 is a view illustrating a structure of a black diamond material; and

FIG. 11 is a table illustrating yields of a semiconductor device when an NE14 treatment is performed and when an NE14 treatment is not performed.

### DETAILED DESCRIPTION

Reference will now be made in detail to the embodiments of the present invention, examples of which are illustrated in the accompanying drawings.

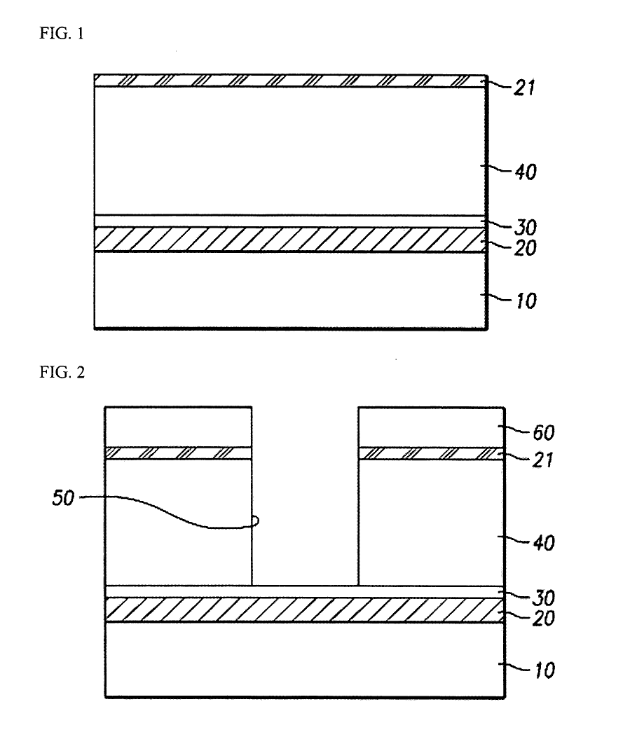

A method for forming a metal line will be described with reference to FIGS. 1 to 5.

First, referring to FIG. 1, a first oxide layer (SiO₂) 20 formed of tetra ethyl ortho silicate (TEOS) is formed on a semiconductor substrate 10. First oxide layer 20 may be formed to have a thickness of about 500-2000 Å using a chemical vapor deposition (CVD) apparatus.

Next, a silicon carbide (SiC) layer 30 is formed on first oxide layer 20 to have a thickness of about 400-600 Å. Then, a porous low-k silicon oxide layer 40 including an alkyl group is formed on silicon carbide layer 30 to have a thickness of about 4,000-6,000 Å.

In one embodiment, for example, silicon carbide layer 30 is formed to a thickness of about 500 Å, and black diamond layer 40 is formed to a thickness of about 5,000 Å, so that a copper metal line including an interlayer insulating layer having excellent thermal and mechanical characteristics can be formed.

At this point, silicon oxide layer 40 including the alkyl group may be a black diamond layer (SiOC) 40. Silicon oxide layer 40 has a low k and better thermal and mechanical characteristics than those of an organic material.

After that, a second oxide layer 21 is formed from TEOS. Second oxide layer 21 can be formed to have a thickness of about 400-600 Å using a CVD apparatus.

Next, referring to FIG. 2, a first photoresist pattern 60 for forming a via hole 50 is formed on second oxide layer 21. Subsequently, second oxide layer 21 and black diamond layer 40 are etched using first photoresist pattern 60 as an etch mask until a portion of silicon carbide layer 30 is exposed, so that via hole 50 is formed.

The etching of second oxide layer 21 and black diamond layer 40 may be performed by a reactive ion etching (RIE) method that uses dual frequencies of 2 MHz and 27 MHz utilizing an addition gas such as Ar, CH₂F₂, CF₄, O₂, C₄F₈, or N₂. An optimized via hole profile can be obtained by etching black diamond layer 40, using such an RIE method that uses dual frequencies and an addition gas.

After the etching, first photoresist pattern 60 is removed.

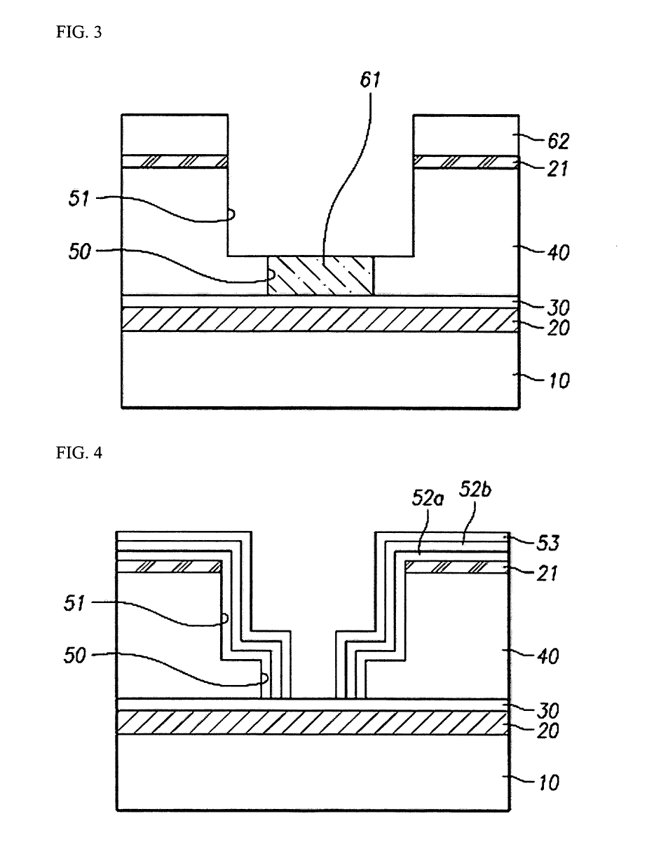

Subsequently, referring to FIG. 3, a photoresist is coated on an entire surface of semiconductor substrate 10 and patterned to leave a portion 61 of the photoresist only inside via hole 50, covering the exposed portion of silicon carbide 30.

After that, a second photoresist pattern 62 for forming a trench, having an opening that exposes via hole 50, is formed on second oxide layer 21.

Next, second oxide layer 21 and black diamond layer 40 are etched a second time using second photoresist pattern 62 as an etch mask to form a trench 51. Here, portion 61 of the photoresist formed inside via hole 50 serves as an etch stop layer.

The second etching of second oxide layer 21 and black diamond layer 40 for forming trench 51 can also be performed by a reactive ion etching (RIE) method that uses a dual frequencies of 2 MHz and 27 MHz, so that an optimized trench profile is obtained. Also, the etching can be performed using an addition gas such as Ar, CH₂F₂, CF₄, O₂, C₄F₈, or N₂.

Next, portion 61 of the photoresist inside the via hole 50 and second photoresist pattern 62 are removed. Here, during the removing of portion 61 of the photoresist and second photoresist pattern 62, a large amount of residual material remaining around the hole is removed using an ashing process and substrate 10 is cleaned with a solution, such as NE14 (a mixture of dimethylacetamide, NH₄F, and water).

Because black diamond (SiOC:H), which is a low-k material having low hardness compared to that of conventional oxide formed from TEOS, can be damaged during an etching process and the plasma process involved in ashing, carbon concentration of a stacked structure including black diamond layer 40, silicon carbide layer 30, second oxide layer 21, and first oxide layer 20, may be reduced.

To compensate for the reduction in the carbon concentration, the stacked structure is processed using a solvent containing fluorine (F), so that the carbon concentration can be restored to a normal concentration. The solvent containing fluorine (F) may be one of NE14, C30T01, and C30T02. NE14 is a compound containing fluorine (F) used for removing organic etching residual and highly-oxidized etching residual. The NE14 has characteristics that allow for immersion for a short time (5-15 minutes) under a low temperature (approximately 40° C.) or also may be used in a spray tool. Moreover, NE14 is completely soluble in water without intermediate rinse. The NE14 can be synthesized using 316LEP stainless steel, Teflon1 PTFE, polypropylene, KYNAR2PVDF, Polyethylene-High density, Polyethylene-UHMW, and PFA. In a cleaning method using NE14, a cleaning is performed for 5-15 minutes at 40° C., rinsed using deionized water (DIW) for 5 minutes, and dried.

Next, referring to FIG. 4, a copper diffusion barrier (52a/52b) is formed on second oxide layer 21 and on exposed portions of black diamond layer 40 in via hole 50 and trench 51. In an embodiment consistent with the present invention, copper diffusion barrier (52a/52b) is formed of a double layer including a TaN layer 52a and a Ta layer 52b. TaN layer 52a may be formed to have a thickness of about 50-200 Å, and Ta layer 52b may be formed to have a thickness of about 100-200 Å.

A copper seed layer 53 is then formed on copper diffusion barrier 52a/52b. Here, copper seed layer 53 may be deposited to have a thickness of about 500-700 Å.

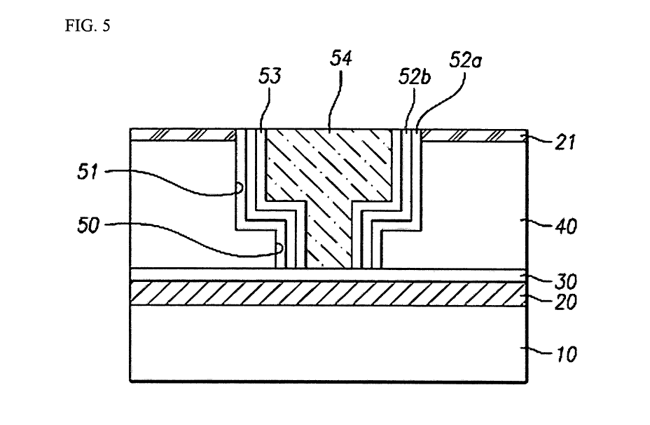

Next, referring to FIG. 5, a copper layer is formed on copper seed layer 53 to sufficiently fill via hole 50 and trench 51 using an electroplating process. After that, semiconductor substrate 10 undergoes heat treatment.

Next, the copper layer is polished using chemical mechanical polishing (CMP) until second oxide layer 21 is exposed, forming a copper metal line 54. After that, subsequent processes are performed to complete the semiconductor device.

Characteristics of a copper metal line consistent with embodiments of the present invention will be analyzed below.

First, characteristics of a profile of a via hole and a trench etched using an RIE method that uses dual frequencies of 2 MHz and 27 MHz and using a gas such as Ar, CH₂F₂, CF₄, O₂, C₄F₈, or N₂ will be descried.

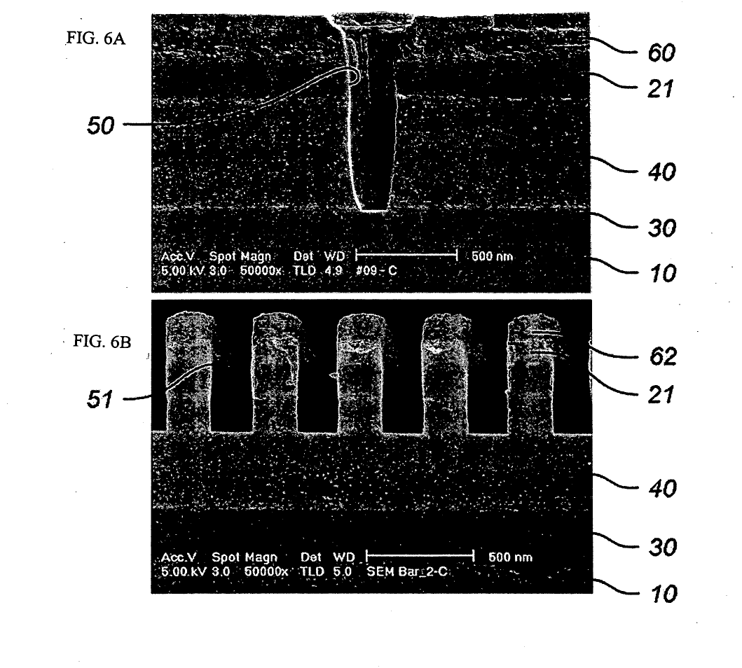

FIG. 6A shows a scanning electron microscope (SEM) image of via hole 50 after via hole 50 is etched in the stacked structure including black diamond layer 401.

Generally, in a conventional dual damascene process, because the hardness of a low-k material is typically 6.3 Gpa, which is very low compared to 71.7 Gpa of fluorine doped silicate glass (FSG) used for an IMD in a related art, bowing can occur. However, the bowing does not appear in the image of via hole 50 in FIG. 6A, and rather, an optimum via hole profile is shown.

FIG. 6B is an SEM image of trench 51. As shown in FIG. 6B, black diamond layer 40 is etched without any irregularities resulting in an optimum profile.

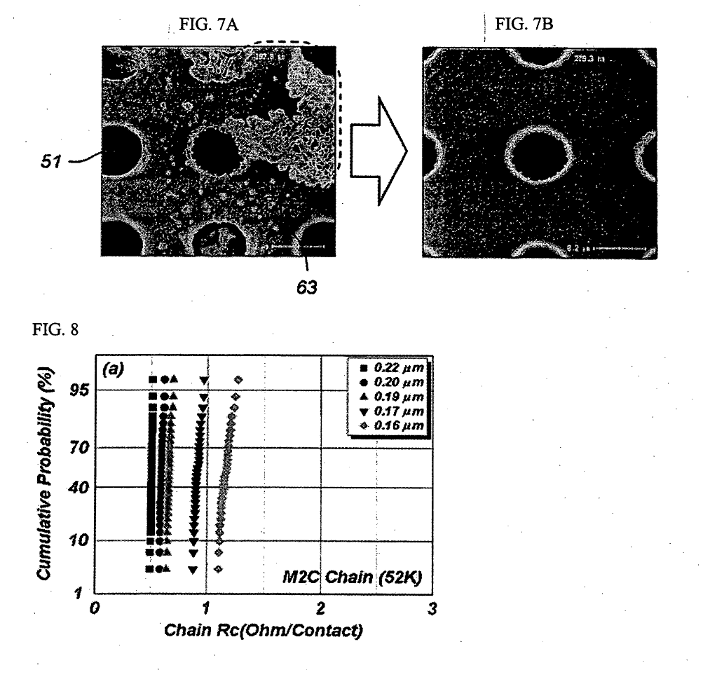

Next, results obtained by performing a cleaning process using an NE14 solution will be described with reference to FIGS. 7A and 7B, which are SEM images of trench 51. As illustrated in FIG. 7A, when an ashing process is performed, a large amount of residue 63 remains around trench 51. However, as shown in FIG. 7B, when a cleaning process is performed using an NE14 solution, not only is residue 63 is removed but also a clean surface is obtained.

FIG. 8 is a graph which illustrates the cumulative probability distribution of contact resistance of a copper line formed by the method consistent with the present invention, where a via hole is cleaned with an NE14 cleaning treatment. As shown in FIG. 8, contact resistance is low for holes having a size in a range of 0.16-0.22 μm, illustrating that the method of forming a semiconductor device consistent with the present invention yields optimal device characteristics.

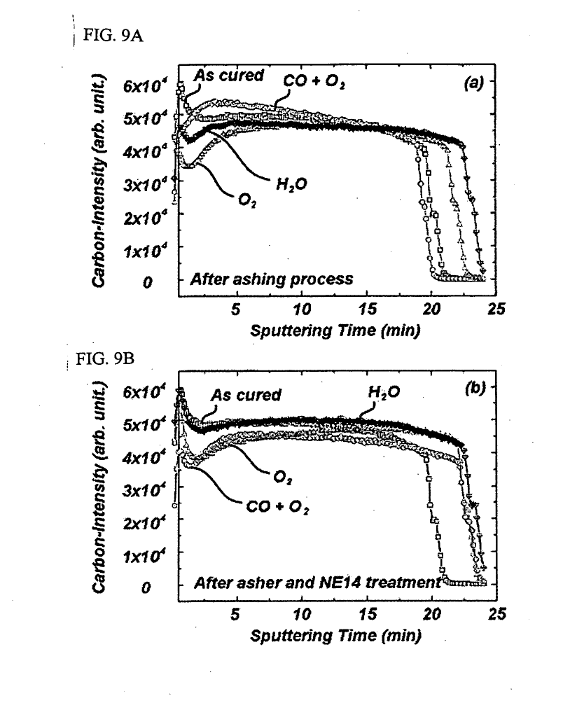

FIGS. 9A and 9B are graphs illustrating carbon intensity versus sputtering time measurement results obtained by secondary ion mass spectroscopy (SIMS), showing the carbon concentration of a stacked structure, such as a stacked structure including black diamond layer 40.

FIG. 9A illustrates a depth profile of a copper metal line formed with a black diamond layer after an etching process is performed. Here, because of surface damage caused by plasma during an ashing process, the copper concentration on the surface is reduced.

On the other hand, FIG. 9B illustrates measurement results obtained by SIMS after an NE14 treatment is performed after an ashing process. As shown in FIG. 9B, the concentration of carbon in a copper metal line formed with a black diamond layer is restored to normal concentration after the NE14 cleaning treatment.

Therefore, the black diamond layer used in the present invention, i.e., a silicon oxide layer including an alkyl group, having a low dielectric constant has better thermal and mechanical characteristics than those of an organic material.

Since an alkyl group's steric hindrance forms a nanometer-sized voids within a thin layer, a low dielectric oonstant can be achieved. In case of an oxide, silicon-oxygen is completely bonded to each other, and spaces between the silicon and oxygen atoms have sizes of less than a nanometer.

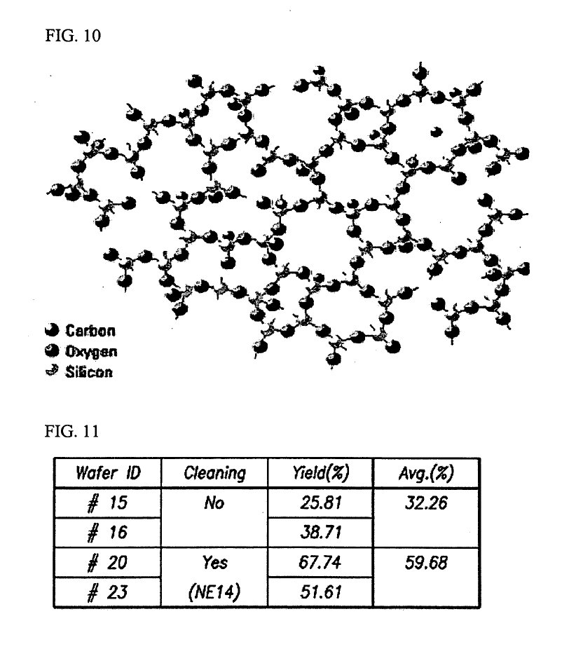

As shown in FIG. 10, which illustrates a molecular construction of a black diamond layer, such as black diamond layer 40, the silicon-oxygen network is broken down by a silicon-methyl (CH₃) formed by irregular reactions occurring during a deposition process, and holes of a nano-level size are formed inside the black diamond layer.

Intermediate portions of the silicon-oxygen network construction can be cut-off under influence of a carbon (C) atom always carrying about two hydrogen (H) atoms with it.

When the silicon-oxygen network construction is cut off in this manner, voids having the sizes of several nanometers are found, resulting in reduction of density of a thin layer on the whole.

Accordingly, a polarization of the thin layer is decreased, so that a low-k thin layer having a dielectric constant k=2.3-2.6, which is far smaller than that of a related art oxide, is formed.

Therefore, a dielectric constant of the thin black diamond layer decreases as the density of an alkyl group increases. However, a too high density of the alkyl group results in weakened thermal and mechanical stabilities.

FIG. 11 is a table illustrating that the yield of a semiconductor device formed consistent with an embodiment of the present invention depends on whether an NE14 cleaning treatment is performed. Residue remaining after an ashing process is effectively removed by the NE14 treatment, and as shown in FIG. 11, results in a substantially higher yield.

Consistent with an embodiment of the present invention, a black diamond layer is used as an IMD, so that a copper metal line having excellent thermal and mechanical characteristics can be formed.

Also consistent with an embodiment of the present invention, a via hole and a trench are etched using an RIE method that uses dual frequencies, so that an optimized etch profile can be obtained.

Also consistent with an embodiment the present invention, carbon concentration of a copper metal line formed using a black diamond layer is restored to normal levels by performing an NE14 cleaning treatment.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for forming a metal line in a semiconductor device, the method comprising:
forming a silicon carbide (SiC) layer on a semiconductor substrate;
forming a silicon oxide layer on the silicon carbide layer, the silicon oxide layer including an alkyl group;
forming a via hole and a trench by removing a portion of the silicon oxide layer;
forming a diffusion barrier on remaining portions of the silicon oxide layer;
forming a copper seed layer on the diffusion barrier; and
forming a copper metal layer on the copper seed layer using electroplating.

2. The method according to claim 1, wherein the silicon oxide layer is a black diamond layer.

3. The method according to claim 2, wherein forming the via hole and the trench comprises:
forming a first photoresist pattern on the black diamond layer, the first photoresist pattern having an opening exposing a first portion of the black diamond layer for forming a via hole;
etching the exposed first portion of the black diamond layer until the silicon carbide layer is exposed using the first photoresist pattern as an etch mask to form the via hole;
removing the first photoresist pattern;
forming a second photoresist pattern for forming a trench, the second photoresist pattern having an opening that exposes a second portion of the black diamond layer;
etching the exposed second portion of the black diamond layer using the second photoresist pattern as an etch mask to form a trench; and
removing the second photoresist pattern.

4. The method according to claim 3, wherein etching the black diamond layer to form the via hole is performed by an RIE (reactive ion etching) method that uses dual frequencies.

5. The method according to claim 4, wherein the RIE method is an RIE that uses dual frequencies of 2 MHz and 27 MHz.

6. The method according to claim 4, wherein the RIE method that uses the dual frequency performs etching using at least a gas selected from a group consisting of Ar, CH₂F₂, CF₄, O₂, C₄F₈, and N₂.

7. The method according to claim 3, further comprising: after the removing the second photoresist pattern, cleaning the semiconductor substrate using a solution containing fluorine (F).

8. The method according to claim 7, wherein cleaning the semiconductor substrate using the fluorine-containing solution restores the carbon concentration of the semiconductor device to a normal concentration.

9. A method for manufacturing a semiconductor device, the method comprising:
forming a first oxide layer on a semiconductor substrate;
forming a silicon carbide layer on the first oxide layer;
forming a silicon oxide layer on the silicon carbide layer, the silicon oxide layer including an alkyl group;
forming a second oxide layer on the silicon oxide layer;
forming a via hole and a trench by removing a portion of the silicon oxide layer and the second oxide layer;
forming a diffusion barrier on remaining portions of the silicon oxide layer and the second oxide layer;
forming a copper seed layer on the diffusion barrier; and
forming a copper metal layer on the copper seed layer using electroplating.

10. The method according to claim 9, wherein the silicon oxide layer is a black diamond layer.

11. The method according to claim 10, wherein forming the via hole and the trench comprises:
forming a first photoresist pattern on the second oxide layer, the first photoresist pattern having an opening exposing a first portion of the second oxide layer for forming a via hole;
etching the exposed first portion of the second oxide layer and a portion of the black diamond layer below the exposed first portion of the second oxide layer until the silicon carbide layer is exposed using the first photoresist pattern as a mask to form the via hole;
removing the first photoresist pattern;
forming a second photoresist pattern for forming a trench, the second photoresist patter including an opening that exposes a second portion of the second oxide layer, and a first portion of the black diamond layer, and the via hole;
etching the exposed second portion of the second oxide layer and the exposed portion of the black diamond layer using the second photoresist pattern as an etch mask to form a trench; and
removing the second photoresist pattern.

12. The method according to claim 11, wherein etching the black diamond layer and the second oxide layer to form the via hole is performed by an RIE method that uses dual frequencies.

13. The method according to claim 12, wherein the RIE method is an RIE that uses dual frequencies of 2 MHz and 27 MHz.

14. The method according to claim 12, wherein the RIE method that uses dual frequencies performs etching using at least a gas selected from the group consisting of Ar, CH₂F₂, CF₄, O₂, C₄EF₈, and N₂.

15. The method according to claim 11, further comprising: after removing the second photoresist pattern, cleaning the semiconductor substrate using a solution containing fluorine (F).

16. The method according to claim 15, wherein cleaning the semiconductor substrate using the fluorine-containing solution restores the carbon concentration of the semiconductor device to a normal concentration.

17. A semiconductor device comprising:
a silicon carbide layer formed on a semiconductor substrate;
a silicon oxide layer formed on the silicon carbide layer, the silicon oxide layer including an alkyl group;
a via hole and a trench formed in the silicon oxide layer;
a copper diffusion barrier formed on inner sidewalls of the via hole and the trench; and
a copper metal layer formed on the copper diffusion barrier and filling the via hole and the trench.

18. The semiconductor device according to claim 17, wherein the silicon oxide layer is a black diamond layer.

19. The semiconductor device according to claim 17, wherein the silicon carbide is formed to have a thickness of about 400-600 Å.

20. The semiconductor device according to claim 17, wherein the silicon oxide layer is formed to have a thickness of about 4,000-6,000 Å.
